(19) United States
(12) Patent Application Publication
(10) Pub. No.: US 2022/0406838 A1
(43) Pub. Date: Dec. 22, 2022

(54) Method for Manufacturing a Biometric Imaging Device by Means of Nanoimprint Lithography

(71) Applicants: WaveTouch Denmark A/S, Taastrup (DK); WaveTouch Limited, Hong Kong (CN)

(72) Inventors: Weiqi Xue, Taastrup (DK); Jørgen Korsgaard Jensen, Taastrup (DK); Peng Xiang, Hong Kong (CN)

(21) Appl. No.: 17/772,974

(22) PCT Filed: Nov. 2, 2020
(86) PCT No.: PCT/EP2020/080668

§ 371 Date: Apr. 28, 2022

(30) Foreign Application Priority Data
Nov. 1, 2019 (EP) 19206784.1

(51) Int. Cl. H01L 27/146; G06V 40/13; G03F 7/00

(52) U.S. Cl. CPC H01L 27/14685; G06V 40/1318; H01L 27/14627; H01L 27/14623; G03F 7/0002; G03F 7/0007

(57) ABSTRACT

The present disclosure relates to a method for fabrication of an optical sensor for use in an image recognition device, e.g. a biometric imaging device, such as a fingerprint detector, for use in under-display applications. The presently disclosed method provides a cost-efficient fabrication process, preferably employing nanoimprint lithography, for realizing an optical sensor with improved light transmittance in a compact and cost-efficient structure. In particular the presently disclosed image recognition device can be placed under a display panel of an electronic device, such as a smartphone. One embodiment relates to a method for manufacturing a biometric imaging device, the method comprising the steps of: providing an image sensor comprising a photodetector pixel array; forming an opaque layer on the first transparent substrate layer or on the photodetector pixel array, the opaque layer having a transparent pinhole array therein; arranging a second transparent substrate layer on top of the opaque layer, and forming a microlens array in the top of the second transparent substrate layer, such that each microlens in the array corresponds to a pinhole in the pinhole array and at least one pixel in the photodetector array, wherein the opaque layer with the transparent pinhole array and the microlens array is formed by means of nanoimprint lithography, such as UV based nanoimprint lithography.

The present disclosure relates to a method for fabrication of an optical sensor for use in an image recognition device, e.g. a biometric imaging device, such as a fingerprint detector, for use in under-display applications. The presently disclosed method provides a cost-efficient fabrication process, preferably employing nanoimprint lithography, for realizing an optical sensor with improved light transmittance in a compact and cost-efficient structure. In particular the presently disclosed image recognition device can be placed under a display panel of an electronic device, such as a smartphone.

### BACKGROUND

Biometric systems, e.g. in the form of fingerprint sensors, have been massively integrated in electronic devices with displays, such as smartphones, tablets, laptops, for privacy and data protection, as well as identity authentication. Today the most common fingerprint sensor is a capacitive sensor that works independent from the display of the device. The present move towards displays covering almost the entire front of the device makes it difficult to integrate the biometric imaging device with the front surface because the capacitive sensors are not easily integrated with the electronics displays

Optical fingerprint sensors can be placed beneath the cover glass of the displays, because reflections from a finger can be scattered back through the cover glass and display to the fingerprint sensor. But in order to avoid a blurred image of the fingerprint, an optical fingerprint sensor typically needs to filter out large angle backscattered reflections from the finger before the light rays impinge the pixels of the sensor array.

An optical sensor addressing these issues is disclosed in pending application PCT/EP2019/061738 from the same applicant, wherein an array of microlenses is provided in combination with an opaque layer with an array of apertures/pinholes and a sensor array such that light can be focused by the microlens structure onto the sensor array through the apertures. PCT/EP2019/061738 is hereby incorporated by reference in its entirety.

### SUMMARY

To achieve a high-resolution sensor with a one-to-one correspondence between a microlens, an aperture and a pixel, the microlenses must be small and the optical setup must be manufactured with high precision, indicating a complex manufacturing process which is sensitive to variations. The present inventors have addressed these issues by forming the optical arrangement of the opaque layer with transparent apertures and the microlens structure directly on top of the image sensor instead of aligning optical structures that already have been manufactured. Hence, one embodiment of the present disclosure relates to a method for manufacturing a biometric imaging device, the method comprising an initial step of providing an image sensor comprising a photodetector pixel array, e.g. a standard CMOS/CCD sensor. A first transparent substrate layer can optionally be arranged on top of the image sensor to cover and protect the image sensor. An opaque layer can then be formed, either on the transparent substrate, as part of the first transparent substrate layer or directly on the photodetector pixel array. The opaque layer can for example be a dark or black polymer layer, e.g. a resin. An array of transparent apertures is provided in the opaque layer such that each aperture corresponds to at least one pixel in the photodetector pixel array In that regard each transparent pinhole may be aligned with at least one pixel in the photodetector pixel array. The formation of the pinholes/apertures in the opaque layer can for example be provided by means of imprint lithography, e.g. nanoimprint lithography, wherein the pinholes are “stamped”/pressed into the opaque layer by means of a mold original with an embossed pattern, which corresponds to the pattern of the pixel array. Alternatively the pinhole array is formed as transparent micro-pillars on or in the first transparent layer and the opaque layer is formed around the micro-pillars, i.e. each transparent micro-pillar corresponds to a transparent pinhole.

On top of the opaque layer with pinholes a second transparent substrate layer can be arranged to cover the opaque layer. In this second transparent substrate layer a microlens array can be formed on or in the top of the second transparent substrate layer, such that each microlens in the array corresponds to a pinhole in the pinhole array and at least one pixel in the photodetector array.

The provision and formation of microlenses can also be provided by means of imprint lithography, in particular nanoimprint lithography, preferably in combination with UV molding, i.e. where the polymer substrate is UV hardened during formation of the microlenses. The form and size of each microlens determines its optical properties, i.e. the optical properties of the microlens array can be precisely controlled when employing nanoimprint lithography in the manufacturing process. One important optical property is the focal point of each microlens and by suitable control of the manufacture process the focal point can be located substantially anywhere along the optical axis of the microlens. In the preferred embodiment the microlens array is formed such that the focal point of each microlens is in the plane of the photodetector pixel array, i.e. such that object light is directly imaged on the photodetector. Alternatively the microlens array is formed such the focal point of each microlens is inside the corresponding pinhole. Thereby imaging on the photodetector array can be similar to the confocal measurement principle. An advantage thereof is that the diameter of each pinhole can be made smaller thereby increasing the angular filtering effect of the imaging device.

The present disclosure also relates to a biometric imaging device manufactured according the fabrication method disclosed herein.

The inventors have hereby realized a manufacture process of a biometric imaging device which is highly accurate, suitable for mass manufacturing and very cost efficient. In particular the initial photodetector array can be a provided directly on silicon wafers of substantially any size, e.g. silicon 300 mm wafers, and even up to third generation 550 mm 650 mm wafers, such that the detector+pinhole array+microlens array of many biometric imaging devices can be manufactured simultaneously.

The presently disclosed biometric imaging device is preferably configured such that the microlens structure is configured to converge an optical signal from above the microlens structure to pinholes in the pinhole array, the optical signal being transmitted to the image sensor array via the pinholes, preferably a single layer of pinholes. Preferably also such that object light, such as fingerprint light, with an incident angle of less than or equal to a predefined value is focused to the photodetector/sensor array whereas object light with an incident angle of more said predefined value is not detected. The predefined value of the incident angle may for example be 20 degrees, or 15 degrees, preferably 10 degrees, more preferably 8 degrees, even more preferably 6 degrees, most preferably 5 degrees. Or even 4 degrees or 3 degrees in selected embodiments. The presently disclosed biometric imaging device may be configured to work with a display panel, e.g. under-display integration, as the light source and/or with one more separate light sources.

The presently disclosed biometric imaging device may further comprise a processing unit for processing the signal from the sensor array in order to recognize an image, e.g. detect a fingerprint. The device may further comprise a storage unit for storing fingerprint information, preferably in encrypted format. The processing unit, the storage unit and the sensor array may be part of one integrated circuit/component.

A further embodiment relates to an electronic device, such as smartphone, tablet, laptop, etc., for optically detecting a fingerprint, comprising a display panel comprising a top transparent layer formed over the display panel as an interface for being touched by a user, and the biometric imaging disclosed herein. The display panel may comprise light emitting display pixels, wherein each pixel is configured to emit light for forming a portion of a display image; and wherein the top transparent layer is configured for transmitting the light from the display panel to display images.

The present disclosure further relates to a method for detecting light returned from an object, such as a fingerprint, on top of a transparent display panel, comprising the steps of focusing and imaging object light to a sensor array of optical detectors by means of microlenses arranged in a microlens structure located below the display panel, wherein the light returned from an object, is received within a predefined incident angle as described above.

### DESCRIPTION OF THE DRAWINGS

The invention will in the following be described in greater detail with reference to the accompanying drawings:

FIG. 1 shows a cut-through side view of an exemplary single microlens of a microlens structure as presently disclosed and a corresponding pixel. The focusing element at the front side of the microlens focuses light on to the pixel by means of a convex front surface.

FIG. 2 shows a cut through view of a schematic diagram of a part of a microlens structure including eleven abutting microlenses arranged in an array.

FIG. 3 shows a perspective illustration of the microlens+pixel shown in FIG. 1.

FIG. 4 shows a perspective illustration of a plurality of the microlenses in FIG. 3 arranged in an array forming part of a microlens structure in front of a pixel array.

FIG. 5 shows another perspective illustration of the front side of an array of microlenses.

FIG. 6 shows the back side of the microlens array in FIG. 5. The circles illustrate the transparent apertures. The remaining part of the back side is opaque.

FIG. 7 shows an example of pixel array that correspond to the microlens array in FIGS. 5-6. The black squares illustrate the pixels.

FIG. 8 shows an illustration of the relations between corresponding microlens, transparent aperture and pixel.

FIG. 9 shows another arrangement of microlenses in a microlens structure where the microlenses are arranged in a hexagonal configuration.

FIG. 10 shows an outline of a cell phone/smartphone with an exemplary position of a biometric imaging device in the form of a fingerprint sensor under the display of the phone.

FIG. 11 shows a cut-through side view of the setup in FIG. 10 where the cover glass is for being touched by a cell phone user is located above an OLED display. The fingerprint sensor is located below the OLED display.

FIG. 12 shows an illustration of the functionality of one embodiment of the presently disclosed biometric imaging device. Reflected light from fingerprint with 0° incident angle is focused by a microlens to the pixel.

FIG. 13 corresponds to FIG. 12 but the incident angle is now 6°. The result is that the light is focused by the microlens and transmitted through the back side of the microlens structure, but with the larger incident angle the focused light does not hit the pixel due to the spacing between sensor array and back side of the microlens structure. I.e. the undesired light with larger incident angle is not detected.

FIG. 14 corresponds to FIG. 12 but the incident angle is now 13°. The result is that the light is focused by the microlens but absorbed by the back side of the microlens structure which is opaque outside of the transparent apertures. I.e. the undesired light with large incident angle is not detected.

FIG. 15A is combination of FIGS. 12-14. The light source used is the OLED display.

FIG. 15B corresponds to FIG. 15A, but the absorbent paint has been exchanged for reflective material.

FIG. 16 is a zoomed in view of FIG. 15A

FIG. 17 is a zoomed in view of FIG. 12

FIG. 18 is a zoomed in view of FIG. 13

FIG. 19 is a zoomed in view of FIG. 14

FIG. 20 shows a wavefront of light with 30° incident angle incident on the microlens array shown in FIG. 2. The light is focused by the microlenses but then absorbed by the opaque surfaces.

FIG. 21 shows a wavefront of light with 30° incident angle incident on the microlens array shown in FIG. 2, however without the apertures, the entire back surface is transparent.

FIG. 22 shows a schematic diagram of a microlens array having an elongated aperture together with two wavefronts having 30° and 0° incident angle.

FIG. 23 shows an illustration of the functionality of a microlens array comprising an elongated aperture. Reflected light from fingerprint with 6° incident angle is blocked by the opaque surface acting to form the aperture.

FIG. 24 shows a cut-through side view illustration of one embodiment of the presently disclosed biometric imaging device manufactured by means of UV-NIL.

FIG. 25 illustrates the process steps of one embodiment of the presently disclosed fabrication method employing UV-NIL.

FIG. 26 illustrates a cut-through enlarged view of one embodiment of the NIL structures that are applied on to the photodetector.

FIG. 27 shows the integration of a biometric imaging device into an electronic device for integration in e.g. a smartphone for under-display applications.

FIG. 28 illustrates the process steps of one embodiment of the presently disclosed fabrication method employing UV-NIL, where the pinholes are formed by stamping an opaque layer.

FIG. 29 illustrates the process steps of one embodiment of the presently disclosed fabrication method employing UV-NIL, where the pinholes are formed by micro-pillars.

### DETAILED DESCRIPTION

Lithography is a process of pattern transfer. When light is utilized this process is termed “photolithography”. When the patterns are small enough to be measured in microns, then this process is referred to as “microlithography”.

“Imprint” referred to in here is meant to indicate pattern transfer in a size of from 1 nm to 10 mm and preferably meant to indicate pattern transfer in a size of from 1 nm to 100 μm (nanoimprint).

Nanoimprint technology is a high-performance, low-cost and volume-capable manufacturing technology for mass production of micro- and nanoscale structures. Nanoimprint technology in which a resin material formed on a substrate is embossed with an undulated pattern in nanometer size (1 to 1000 μm) of a mold by pressing the two together has attracted attention recently. Nanoimprint technology advantageously allows a component with a variety of characteristics to be produced at low costs as compared with conventional pattern-forming processes involving lithography and etching. This is because nanoimprinters have a simple configuration and are not so expensive than conventional apparatuses and further because it takes a short time to mass-produce components with the same shape. Nanoimprint lithography (NIL) is a development advanced from embossing technology well known in the art of optical disc production, which comprises pressing a mold original with an embossed pattern formed on its surface (this is generally referred to as “mold”, “stamper” or “template”) against a resin, typically a polymer, to thereby accurately transfer the micropattern/nanopattern onto the resin through mechanical deformation of the resin. In this, when a mold is once prepared, then microstructures such as nanostructures can be repeatedly molded, such that it is suitable for mass manufacturing.

UV molding is a cost-effective method of producing micro-optics on wafer scale. Here, a liquid polymer resin is UV-cured between a substrate (e.g. glass or semiconductor wafer) and a transparent molding tool in a contact mask aligner.

Polymeric lens molding can be provided where lens patterns are transferred into optical polymer materials by soft UV imprint lithography using working stamps replicated from the wafer-size master stamps, thereby providing hybrid and monolithic microlens molding processes, which can be adapted to various material combinations for working stamp and microlens materials.

UV-based nanoimprint lithography (UV-NIL) combines UV molding with nanoimprint lithography. In particular SmartNIL offered by EV Group is a full-field imprint technology based on UV exposure, providing a lithography technique in many structures size and geometry capabilities. SmartNIL incorporates multiple-use polymer stamp processing.

A first preferred embodiment of the present disclosure relates to a method for manufacturing a biometric imaging device, the method comprising the steps of:
providing an image sensor comprising a photodetector pixel array;
forming an opaque layer on the first transparent substrate layer or on the photodetector pixel array, the opaque layer having a transparent pinhole array therein;
arranging a second transparent substrate layer on top of the opaque layer, and
forming a microlens array in the top of the second transparent substrate layer, such that each microlens in the array corresponds to a pinhole in the pinhole array and at least one pixel in the photodetector array,
   wherein the opaque layer with the transparent pinhole array and the microlens array is formed by means of nanoimprint lithography, such as UV based nanoimprint lithography.

Another embodiment relates to a method for manufacturing a biometric imaging device, the method comprising the steps of:
providing an image sensor comprising a photodetector pixel array;
optionally arranging a first transparent substrate layer to cover the image sensor;
forming an opaque layer on the transparent substrate or on the photodetector pixel array, the opaque layer having a transparent pinhole array wherein each pinhole is aligned with a pixel in the photodetector pixel array;
arranging a second transparent substrate layer to cover the opaque layer, and
forming a microlens array in the top of the second transparent substrate layer, such that each microlens in the array is aligned with a pinhole in the pinhole array and a pixel in the photodetector array.

In the preferred embodiment the a biometric imaging device comprises a single microlens array layer and a single aperture array layer, where the individual microlenses in the microlens array correspond to the individual apertures in the aperture array. Each pair of corresponding microlens and aperture corresponds to at least one pixel in the sensor array.

With nanoimprint lithography, and in particular UV-based nanoimprint lithography, the presently discloses method can be executed in a single manufacturing procedure where all layers of the presently disclosed biometric image sensor are formed by molding and demolding, e.g. all layers are not only formed/molded with UV curable resists directly on the image sensor, but also aligned automatically with each other after the demolding such that the manufacturing process is very efficient and such that the wished correspondence between the microlens array, the aperture array and the pixel array is obtained.

The thickness of the optional first transparent substrate layer is preferably at least 5 μm, more preferably at least 10 μm, most preferably at least 20 μm. Furthermore, the thickness of this layer is preferably less than 100 μm, more preferably less than 50 μm, most preferably less than 25 μm, such as 24 μm. The advantages of the first transparent layer are both to cover and protect the pixel array but also to ensure a certain predefined distance between the aperture array and pixel array. This distance is typically selected to correspond to the back focal length of the microlenses. This spacing ensures that part of undesired light which is transmitted through the transparent aperture, e.g. incoming light with an incident angle which is slightly higher than the predefined angle, does not hit the corresponding pixel. However, the first transparent substrate layer may also be thinner, such as less than 20 μm, more preferably less than 10 μm, even more preferably less than 5, 4, 3 μm or most preferably less than 2 μm.

The thickness of the second transparent substrate layer is kept small to ensure a small overall thickness of the biometric imaging device, hence preferably the thickness of this layer is less than 500 μm, more preferably less than 200 μm, even more preferably less than 100 μm, most preferably less than 50 μm, such as 48 μm. Furthermore, the thickness of this layer must be large enough to ensure a correct imaging from the microlens to the pixel on the sensor. Hence preferably the thickness of this second substrate layer is at least 10 μm, more preferably at least 25 μm, most preferably at least 40 μm.

The opaque layer must be thick enough to ensure non-transparency of the light. The opaque layer may be applied as a resist/polymer layer, e.g. a black resist/polymer layer, alternatively a resist/polymer layer which becomes non-transparent/coloured upon hardening, e.g. UV hardening. E.g. with a black layer, the thickness can be around 1 μm, e.g. it can merely by a layer of dark or black paint for example applied onto the first substrate layer. Hence preferably the thickness of this second substrate layer is at least 1 μm, more preferably at least 5 μm, most preferably at least 8 μm. However, the layer can also be made thicker to increase the filtering effect of the pinholes. Hence, the thickness of the opaque layer is preferably less than 50 μm, more preferably less than 25 μm, even more preferably less than 25 μm, yet more preferably less than 12 μm, such as 10 μm, but even more preferably less than 5, 4 or 3 μm, most preferably less than 2 μm, such as between 1 and 2 μm. A thin opaque layer of less than 3 μm, such as between 1 and 2 μm, can be an advantage within nanoimprint technology because the process is quicker with thinner layers. The optical setup of the presently disclosed biometric imaging device, where a microlens focuses the light, through a single pinhole, to the photodetectors, can loosen the requirement on the thickness of the opaque pinhole layer down to around 1 μm without sacrificing the optical power and optical resolution.

The total thickness of the following layered structures: optional first transparent substrate layer, opaque layer and second transparent substrate layer with microlenses is preferably less than 500 μm, more preferably less than 250 μm, even more preferably less than 150 μm, and most preferably less than 100 μm, even less than 85 μm.

The diameter of each pinhole must be large enough to ensure light transmittance through the pinhole. Hence, preferably the diameter of each pinhole is at least 1 μm, more preferably at least 4 μm, most preferably at least 8 μm, such as 10 μm. But the diameter of the pinhole must also be small enough to ensure a filtering effect of stray light to increase the signal to noise ratio of the biometric imaging device. Hence, preferably the diameter of each pinhole is less than 50 μm, more preferably less than 25 μm, even more preferably less than 25 μm, most preferably less than 12 μm.

The radius of curvature of each microlens in the microlens array is preferably selected to ensure that the focal point (with the corresponding wavelength of the received light) of the microlens substantially corresponds to the size and the location of a corresponding at least one pixel in the sensor array. Hence, preferably the radius of curvature of each microlens is less than 250 μm, more preferably less than 100 μm, most preferably less than 50 μm. Also preferably at least 10 μm, more preferably at least 20 μm, most preferably between 20 and 40 μm, such as 30 μm.

As each microlens corresponds to one or more pixels, the microlenses are typically quite small and the optical setup must be manufactured with high precision in order for such a biometric imaging device to function properly. Hence, preferably the pinhole to microlens axes and/or the pinhole to pixel axes are aligned within ±5 μm, more preferably within ±2 μm, most preferably within ±1 μm or even better. As stated above nanoimprint technology is one way to achieve such high precision with low manufacturing cost.

### Biometric Imaging Device

A major advantage of the present invention is that the microlens structure can focus the desired light such that the desired light within the predefined incident angle can be imaged to pixels on a sensor array. Compared to prior art solutions this means that more of the desired light is detected, i.e. the present microlens structure has a higher transmittance of the desired light. With more light to the detector am object, such as a fingerprint, can be detected faster and/or more precisely.

With the present microlens structure it is also possible to focus the light such that only part of the pixels, for example in a standard CCD or CMOS array, is used for detection, possibly only one third of the pixels. This makes it possible to use a sensor array with much fewer pixels which will be much faster to read, i.e. the fingerprint sensor can detect a fingerprint faster.

Alternatively a plurality of neighbouring pixels of the sensor array is assembled in groups, and wherein each group of pixels is configured to function as one active pixel such that the sensor array comprises only one active pixel for each microlens. Then each aperture and corresponding microlens corresponds to more than one pixel in the sensor array.

The pixel could be a pixel of a CCD (Charge Coupled device), CMOS (Complementary Metal Oxide Semiconductor) or a photodiode. The terms “sensor array”, “sensor pixel array”, “photodetector array” and photodetector pixel array” are used interchangeably herein.

Another advantage is that the presently disclosed structure can be made very compact. The prior art solutions need a certain height of the absorbing channels in order to function properly. The absorbing channels typically have a height of 300-500 μm, whereas the present microlens structure can be made with a height of only 50-100 μm. This fits much better with the current trend of making electronic display devices thinner and thinner.

Each focusing element of the microlens structure can be customized to a certain optical design and configuration. The focusing elements can be spherical, aspherical, pyramid-shaped, convex, concave, etc. The design depends on the medium surrounding the microlens. For example, if the interface is air the focusing element would typically be spherical. If the interface is glue, the focusing elements would typically be aspherical. The back side can be plane but could also be designed to help with focusing of the light, back focal length adjustment, aberration correction, etc. E.g. spherical, aspherical, pyramid-shaped, convex, concave, etc.

In order to reduce cost the present microlens structure is advantageously manufactured such that all focusing elements, i.e. microlenses, are identical.

The microlens structure is preferably configured such that each of said focusing elements is in optical correspondence with one of said transparent apertures. These transparent apertures help to ensure that only light within the predefined incident angle is transmitted to the sensor array. Undesired light can for example be scattered or absorbed such that it does not hit the detector/sensor array. The microlens structure may for example be configured to absorb or scatter at least part of the fingerprint light having an incident angle of more than said predefined value, or an incident angle within a predefined angular range, e.g. within an angular range of 1-5 degrees, or 2-7 degrees, or 3-8 degrees, or 4-9 degrees. E.g. the microlens structure can be configured to be light absorbing except for the front side with the focusing elements and the transparent apertures which are light transmissive.

In the preferred embodiment the presently device is configured such that object light is focused and imaged to the sensor array. I.e. each microlens may be configured to focus and/or image fingerprint light to a corresponding pixel on the sensor array. Hence, the microlens structure may be configured such that each focusing element is capable of converging fingerprint light through a corresponding transparent aperture of the back side of the microlens structure. Hence, a microlens is not necessarily aligned with the corresponding aperture and the corresponding at least one pixel, as long as they are in optical correspondence such that the light is focused by the microlens, through the corresponding aperture and on to the corresponding at least one pixel. Focusing may for example be provided by providing at least a part of or all of the focusing elements with a spherical surface. Alternatively the focal point of each microlens may be provided elsewhere, e.g. inside the corresponding transparent aperture, but preferably centred in the aperture.

In the preferred embodiment there is no interface between the individual microlens elements in the microlens structure, the bulk inside the microlens is preferably a solid uniform block of a transparent material. The optical properties of the presently disclosed optical sensor could be improved if the side surfaces, i.e. the surfaces connecting the front and back sides, of each individual microlens element were opaque such that undesired light could be absorbed by the side surfaces. However, that would make the microlens structure much more complicated and expensive to manufacture. Instead the optical properties can be controlled by the aperture array which can be cost-efficiently designed and manufactured.

A stated previously the sensor array may be a standard CCD sensor array. However, as typically only between ¼ and ½, possibly even between 1/10 and ½, of the pixels in a standard sensor are actually used in this setup, the sensor array used herein may be configured to comprise only one pixel for each microlens. Fewer pixels make read-out of the sensor array much faster, such that object detection can be more efficient.

The presently disclosed biometric imaging is typically optically designed to match a predefined display panel where the distance from the touch surface to the microlens structure provides an optical constraint for the design of the microlens structure and the sensor array. With a standard off-the-shelf sensor array the pixel size is predefined which provides another optical constraint. With a customized sensor array the pixel size can be part of the optical design space.

In a further embodiment the presently disclosed optical sensor comprises at least one optical filter. Such an optical filter may be a colour filter that can be configured to filter out light of a predefined wavelength range, such as undesired background light. A filter may also be configured such that only the wavelength range of the light source is allowed to pass. E.g. if an IR light source is use, the colour filter can be configured to transmit only IR light. An OLED display panel typically employs light with three different wavelength ranges. The colour filter can then be configured to transmit only one or two of these wavelength ranges. A filter may for example be provided between the backside of the microlens structure and the sensor array, e.g. just in front of the sensor pixel array.

The presently disclosed biometric imaging device may be configured to utilize light from a light emitting display panel, e.g. a display panel of an electronic device, e.g. by using the OLED light sources that typically are part of a display panel. However, an OLED typically illuminates light both upwards towards the display surface and downwards—towards the biometric imaging device. The preferred solution is to provide at least one (separate) light source for transmitting light such that light is transmitted out from the touch surface where the fingerprints will be located. The light source(s) may advantageously be configured for emitting infrared light, such as around 700-900 nm or 800-900 nm, alternatively or additionally green light. However, other wavelength ranges are possible. The light source may at least one laser or LED which can be provided very cost efficiently and very compact. There are many solutions to integrate one or more light sources such that light is transmitted out from the touch surface.

The transparent apertures can also be provided by making at least a part of the back side of the microlens structure at least partly reflective, such as fully reflective or partly reflective partly absorptive. This can be provided by attaching a reflective material to the back side of the microlens structure as exemplified in FIG. 15B, where reflective material has been attached to the back side of the microlens structure, i.e. below the microlens structure, to create the transparent apertures between the reflective material elements. The advantage of this solution is that light incident on the reflective back side can be reflected back towards the display panel and thereby be used for illuminating an object such as a fingerprint on the display panel. I.e. less photons are wasted due to absorption in the microlens structure but can be reused for illumination thereby increasing the utilization of the light source and improving the efficiency of the device.

In one embodiment of the present disclosure a reflective back side of the microlens structure is provided by means of a metal, such as a metal foil, such as an aluminium foil, which can be attached to the back side of the microlens structure. The transparent apertures can be provided by cutting and/or stamping holes in the metal foil such that correspondence is provided with the individual microlenses of the microlens structure.

In one embodiment of the presently disclosed biometric imaging device, the distance between the front side and the back side of the microlens structure is less than 400 μm, more preferably less than 300 μm, even more preferably less than 200 μm, yet more preferably less than 100 μm, even more preferably less than 75 μm, yet more preferably less than 60 μm, most preferably less than 55 μm. The focusing elements, i.e. the microlenses, of the microlens structure may have a diameter of less than 100 μm, more preferably less than 50 μm, even more preferably less than 30 μm, most preferably less than or around 25 μm. The individual focusing elements may be configured to have a back focal length of less than 30 μm, more preferably less than 20 μm, more preferably less than 15 μm, most preferably less than or approx. 10 μm. Hence, the footprint of the microlens structure in the plane of the sensor array may therefore be less than 400 mm², more preferably less than 200 mm², most preferably less than or around 100 mm².

The total height of the presently disclosed biometric imaging device may consequently be less than 500 μm, more preferably less than 300 μm, more preferably less than 200 μm, even more preferably less than 150 μm, most preferably less than 100 μm.

The optical sensor may substantially square or rectangular. However, a substantially elongated embodiment is also an option such that the sensor becomes a line scanner.

### Array of Transparent Pinholes/Apertures

The terms “pinhole” and “aperture” and “aperture array” and “pinhole array” are used interchangeably because with the very limited thickness of the opaque layer in the present disclosure, an “aperture” in the layer can be substantially equated with a “pinhole” in the layer.

The pinholes are transparent such that light can pass through the pinholes whereas light is blocked by the opaque layer surrounding the pinholes. Transparency of the pinholes can be provided if the pinholes are actual holes, i.e. no material, e.g. filled with air. However, alternatively the pinholes can be at least partly or fully filled with a transparent material. One advantage of such a solution is that optical interfaces between air and transparent material can be reduced, e.g. the interface between the microlens structure and the pinhole or the interface between the pinhole and the first transparent layer, and thereby optical noise of the biometrical imaging device can be reduced.

Transparent pinholes/apertures as actual holes of air in the opaque layer can be provided by stamping out the corresponding array pattern in the opaque layer, e.g. by means of nanoimprint technology as described herein.

Transparent pinholes/apertures consisting of a transparent material, i.e. a transparent polymer can be provided in different ways. One way is first stamp out holes in the opaque layer and subsequently fill transparent material into the holes, e.g. if the transparent material is initially provided as a low-viscous resin that can flow into the holes. The advantage of such a solution is that it can be the second transparent layer, wherein the microlenses are formed, that flows into the pinholes upon application of the layer. But that solution requires a certain low viscosity of the resin in combination with the size of the diameter of each pinhole, i.e. if the pinhole is too small, it requires a very low viscosity of the resin to flow into the pinhole.

Another solution is to form an array of transparent micro-pillars, each micro-pillar corresponding to a transparent pinhole, and subsequently provide the opaque layer around the micro-pillars. An advantage of this solution is that the array of transparent micro-pillars can be formed in the first transparent layer. The micro-pillar solution can also be provided by means of nanoimprint technology and provides for very small pinholes.

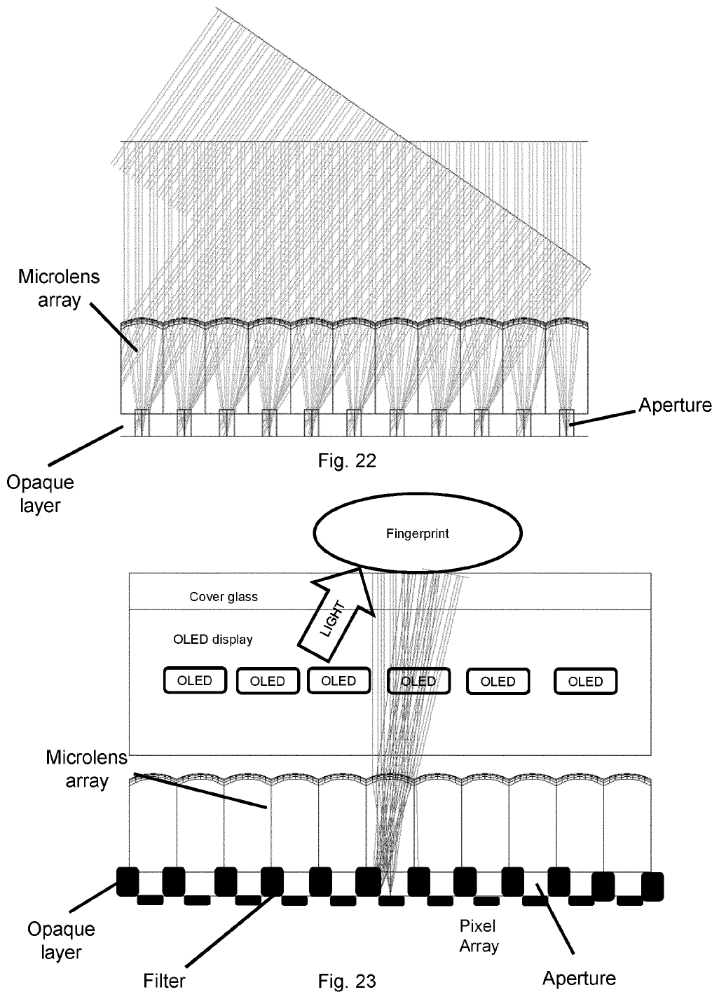

In an additional embodiment of the present disclosure the apertures have a significant thickness along an axis perpendicular to the major plane of the apertures, such as at least 3 μm, more preferably at least 6 μm, even more preferably at least 9 μm, yet even more preferably at least 12 μm, most preferably at least 15 μm, in order to form elongated, e.g. cylindrical, apertures. The thickness of the elongated apertures of the microlens structure may have a significant impact on the ability of the apertures to filter out undesired light with large incident angles. The non light transmissive parts of the backside of the microlens structure, acting to form the apertures, may have a similar thickness as the light transmissive/optically transparent apertures. Alternatively, the opaque, non light transmissive, parts may be applied in a substantially three-dimensional configuration for formation of elongated apertures having a substantial thickness along an axis perpendicular to the sensor array, such as at least 3 μm, more preferably at least 6 μm, even more preferably at least 9 μm, yet even more preferably at least 12 μm, most preferably at least 15 μm. A larger thickness of the elongated apertures may decrease the incident angle at which light can pass the aperture without being blocked/absorbed by the opaque layer. Having a significant thickness of the elongated apertures, such as at least 3 μm, more preferably at least 6 μm, even more preferably at least 9 μm, yet even more preferably at least 12 μm, most preferably at least 15 μm, may lead to the negating of the need for a space between the apertures and the sensor array. Such that object light with a large incident angle may be blocked or absorbed by the aperture. Elongated apertures/pinholes are exemplified in FIGS. 22 and 23.

Alternatively the aperture layer is quite thin, preferably less than 5, 4 or 3 μm, most preferably less than 2 μm, such as between 1 and 2 μm. A thin opaque layer of less than 3 μm, such as between 1 and 2 μm, can be an advantage within nanoimprint technology because the process is quicker with thinner layers.

The transparent apertures may advantageously have a cross-sectional area of less than 800 μm², more preferably less than 400 μm², more preferably less than 200 μm², most preferably less than or around 100 μm². I.e. the apertures may be cylindrical.

### Spacing Between Microlenses, Apertures and Sensor Array

In an additional embodiment of the present disclosure means for electrically insulating the sensor array from the aperture array are provided. Insulating means may comprise the use of a layer between the sensor array and the aperture array, wherein the layer may consist of a gap, such as an air gap, or by a material which is substantially an insulator, e.g. a transparent polymer as exemplified herein. By the incorporation of an insulating layer, the aperture array may be fabricated in a conductive material facing the sensor array containing the photoelectric pixels, without risking that the arrangement leads to a distorted output signal of the sensor array, such as comprising an increase in noise, or even short-circuit of the assembly. Preferably, the apertures comprise one optical filter, or multiple optical filters, such as one for each microlens, that is configured to filter out light of a predefined wavelength range, such as undesired background light. The filter may also be configured such that only the wavelength range of the light source is allowed to pass. The filter may be provided in the same layer as the apertures of the microlens structure. The filter layer may further comprise a single filter for each microlens, such that each filter is surrounded by the non light transmissive paint. In this way, the light filter may constitute, or form part of, the aperture. For example, each aperture of the microlens structure may comprise a filter.

In an additional embodiment, the aperture array may be in contact with the sensor array, but may in another embodiment be positioned adjacent, with a gap, to the sensor array.

In an additional embodiment of the present disclose, the apertures are in contact with the microlens layer. Alternatively, the apertures may not be in contact with the microlens layer, such that there is a gap between the microlens array and the apertures.

### Lens Properties

As used herein, a lens (e.g. a microlens) include, but are not limited to elements with a cross-sectional structure that is hemispherical, aspherical, conical, triangular, rectangular, polygonal, or a combination thereof along a plane perpendicular to the microlens structure of the lens through the centre of the lens.

The lens may have optical properties such that it is substantially transparent to at least the light returned from the object. Further, the lens may have a refractive index above 1, preferably at least 1.1, more preferable at least 1.2, even more preferable at least 1.25, most preferable at least above 1.25. Preferably collimated incident light is focused by the microlens into a single point located in the focal plane of the microlens.

In an additional embodiment of the present disclosure the lenses are lenticular lenses, such as linear lens arrays and/or two-dimensional lens arrays such as close-packed hexagonal or any other two-dimensional array. The apertures of a microlens structure employing lenticular lenses may be, but are not limited to, the use of slits instead of pinhole apertures. In further embodiments of the present disclosure, the apertures have other shapes such as rectangular, such as a square, oval or polygonal.

### Examples

FIG. 1 shows a cut-through side view of an exemplary single microlens of a microlens structure as presently disclosed and a corresponding pixel. The focusing element at the front side of the microlens focuses light on to the pixel by means of a convex front surface. The convex front surface functions as focusing element when located in a medium with lower refraction index than itself, such as air. Part of the back side is painted to opaque. Unpainted part is the transparent aperture. Desired light pass through the aperture then hit the pixel which is an optical detector. Undesired light is absorbed by the paint, filtered by the filter, or hit outside of the pixel. The front side of the microlens in FIG. 1 is a sphere with radius of curvature of 24 microns, while the back side is a plane. The length of the microlens is 54 microns, width and height are both 24 microns. Back focal length is 13 microns. The transparent aperture in the center of the back side is circular and it formed by painting the rest of the back side opaque or making it rough. The size of the corresponding pixel is 8×8 microns. The center of the front side, back side and the pixel is one-to-one-correspondence. In other words, they are co-axial. The microlens is designed to be exposed to air, i.e. the interface to the front side and the back side of the microlens should be air. A filter in front of the pixel is provided to filter light with undesired wavelengths, e.g. by only allowing light with the signal wavelength pass. A suitable filter can significantly reduce background light.

The size of the area sensitive to fingerprints depends on the practical necessity. In order to provide a 10 mm×10 mm area which is sensitive to fingerprint, then a 417×417 array of microlenses and pixels as illustrated in FIG. 1A would be suitable.

In another example the front side of the microlens is spherical with radius of curvature of 50 microns, while the back side is a plane. The length of the microlens is 100 microns, width and height are both 50 microns. Back focal length is 20 microns. The transparent aperture in the center of the back side, i.e. co-axial, is circular with a diameter of 20 microns. The size of the corresponding pixel is 15×15 microns. The microlens is designed to be exposed to air

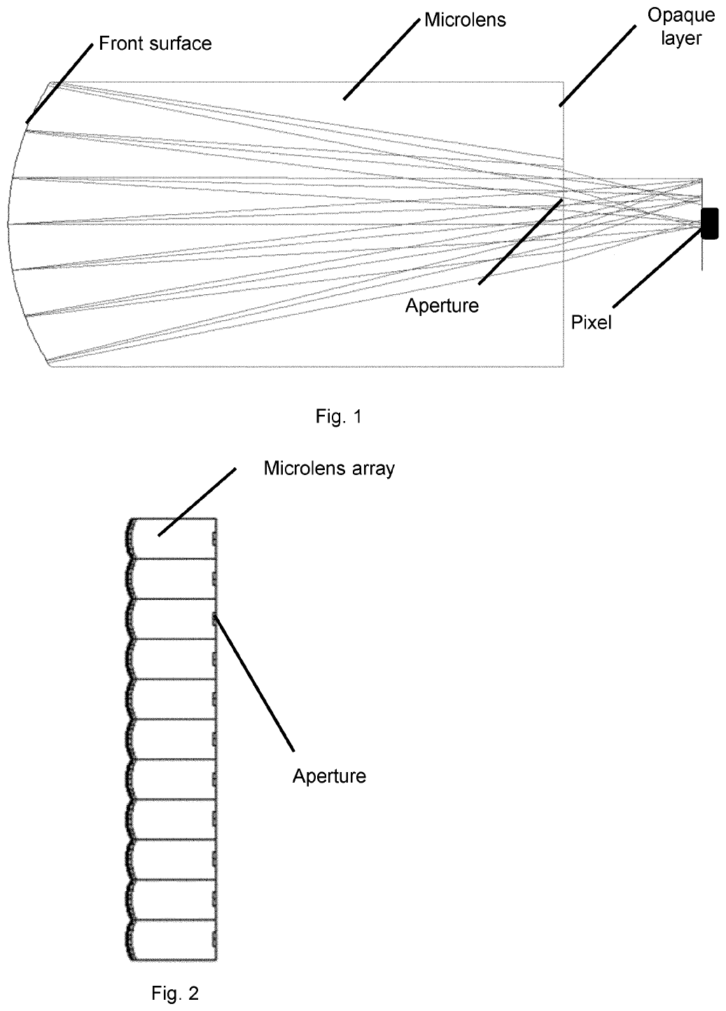

FIG. 2 shows cut through view of a schematic diagram of a part of a microlens structure including eleven abutting microlenses arranged in an array. Even though the individual microlenses are indicated with horizontal there is no interface between the microlenses, because optical isolation between the microlenses is not necessary, this reduces the manufacturing cost. This is in contrast to the prior art optical channel solution where optical isolation between neighboring channels is necessary.

FIG. 3 shows a perspective illustration of the microlens+pixel shown in FIG. 1A. The transparent side surfaces are indicated.

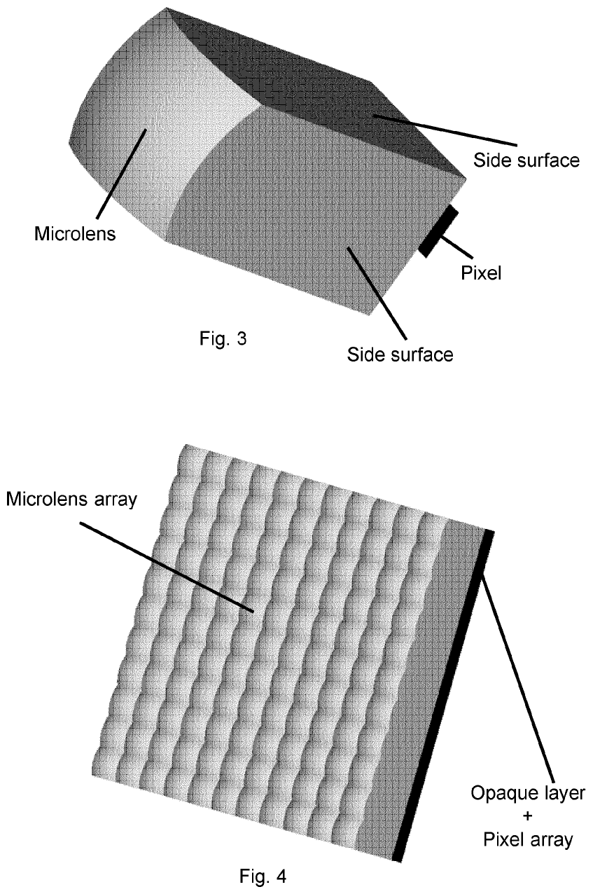

FIG. 4 shows a perspective illustration of a plurality of the microlenses in FIG. 3 arranged in an array forming part of a microlens structure in front of a pixel array. As a practical implementation typically comprises many thousands of microlenses the illustrated array of 121 microlenses is only a very small part of an actual microlens structure.

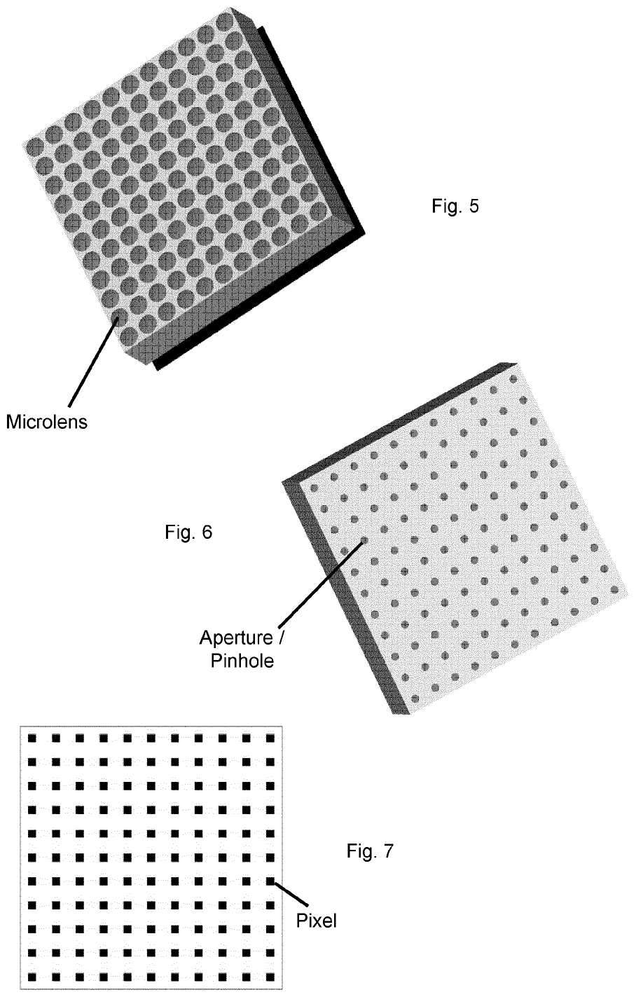

FIG. 5 shows another perspective illustration of the front side of an array of microlenses. The example in FIG. 5 shows circular fronts, but other options are possible, e.g. hexagonal, triangular, etc. As long as an area can be formed.

FIG. 6 shows the back side of the microlens array in FIG. 5. The circles illustrate the transparent apertures. The remaining part of the back side is opaque or rough such that undesired light is absorbed. The shape of the aperture could also be square, hexagonal, other equilateral polygons, but circular is the most preferred. Without optical isolation between neighboring microlenses, the transparent apertures are important for filtering/absorbing undesired light.

FIG. 7 shows an example of pixel array that correspond to the microlens array in FIGS. 5-6. The black squares illustrate the utilized pixels. Each square represents one effective pixel. The shape of the individual pixel could vary as well, the size of the pixels is part of the optical design. The effective pixel could be one pixel or a plurality of pixels, such as CCD pixels, COMS pixels and photodiodes. Assembling several (neighboring) pixels to one effective pixel in a sensor array can be controlled by software.

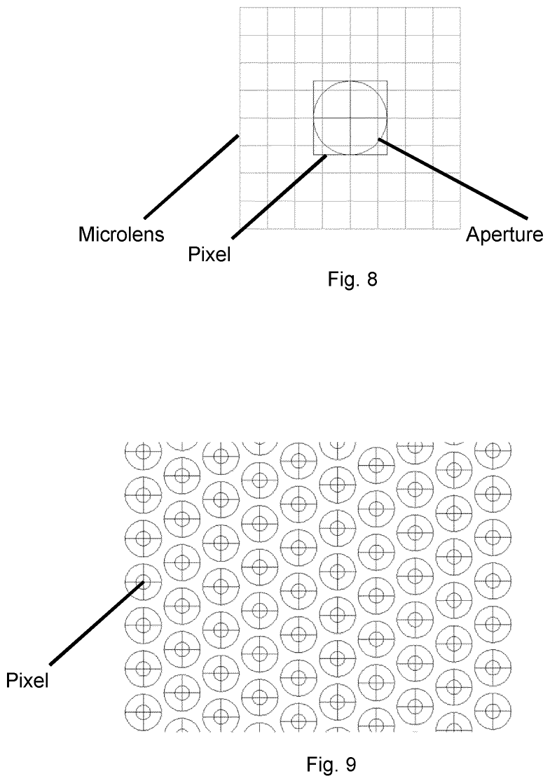

FIG. 8 shows an illustration of the relations between corresponding microlens, transparent aperture and pixel. In this case, a single microlens is square. The aperture is circular and with as substantially smaller area. The pixel is square corresponding in diameter to the aperture. A square microlens arrangement as illustrated makes full use of the front side of the micro lens array. It collects as much light as possible and thereby improves light transmittance compared to prior art optical fingerprint sensors.

FIG. 9 shows another arrangement of microlenses in a microlens structure where the microlenses are arranged in a hexagonal configuration. Compared to the square arrangement in FIG. 9 this hexagonal arrangement will typically have less light transmittance because the spatial arrangement of the microlenses is less space efficient.

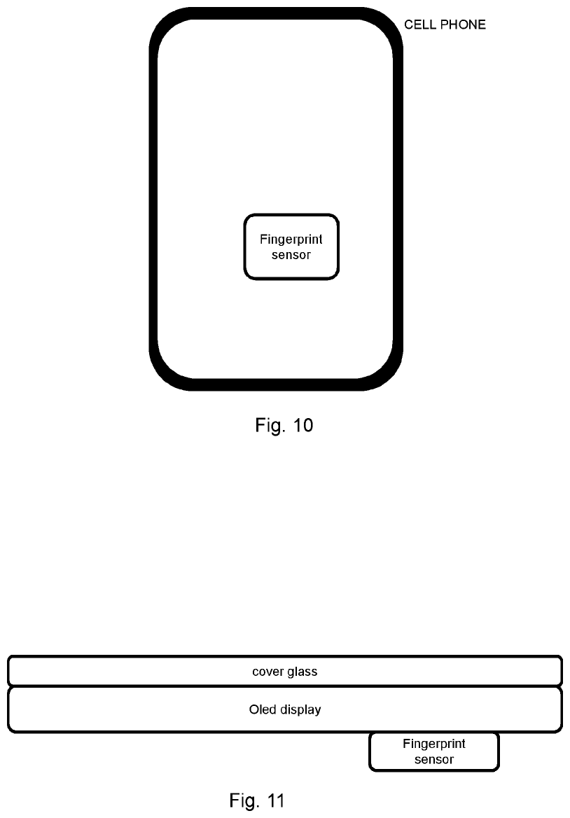

FIG. 10 shows an outline of a cell phone/smartphone with an exemplary position of a fingerprint sensor under the display of the phone. As long as the cellphone has a transparent display the presently disclosed optical sensor and fingerprint detector can be mounted anywhere under the display.

FIG. 11 shows a cut-through side view of the setup in FIG. 10 where the cover glass is suitable for being touched by a cell phone user is located above an OLED display. The fingerprint sensor is located below the OLED display. The sizing in FIG. 11 is not shown realistically because the presently disclosed fingerprint detector will typically be much thinner than a display panel+cover glass.

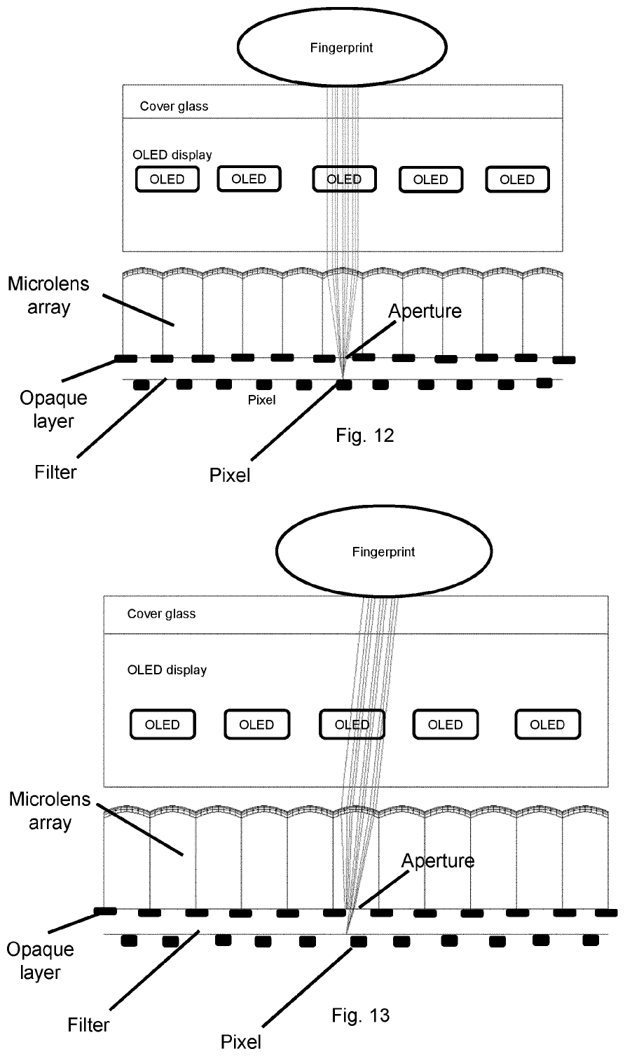

FIG. 12 shows an illustration of the functionality of one embodiment of the presently disclosed optical sensor. Reflected light from a fingerprint with 0° incident angle is focused by a microlens to the corresponding pixel. Before it reaches the microlens array, the reflected light passes though the cover glass and the transparent or translucent display panel. In other means, the presently disclosed optical sensor and image recognition device can be mounted under other transparent or translucent material.

FIG. 13 corresponds to FIG. 12 but the incident angle of the reflected light is now 6°. The result is that the light is focused by the microlens and transmitted through the back side of the microlens structure, but with the larger incident angle the focused light does not hit the pixel due to the spacing between sensor array and back side of the microlens structure. I.e. the undesired light with larger incident angle is not detected.

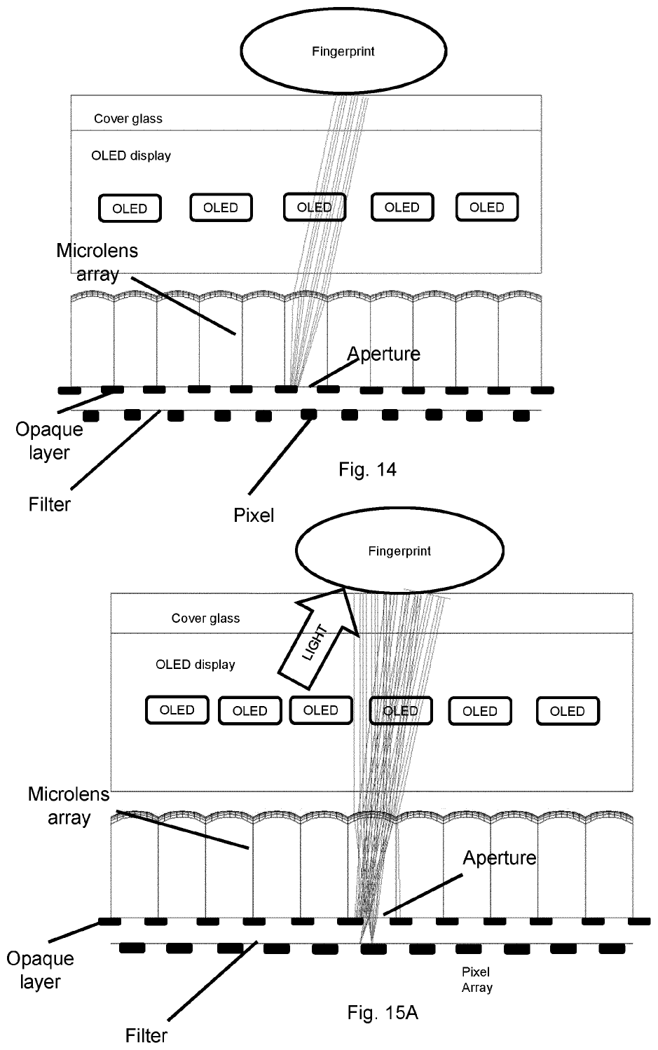

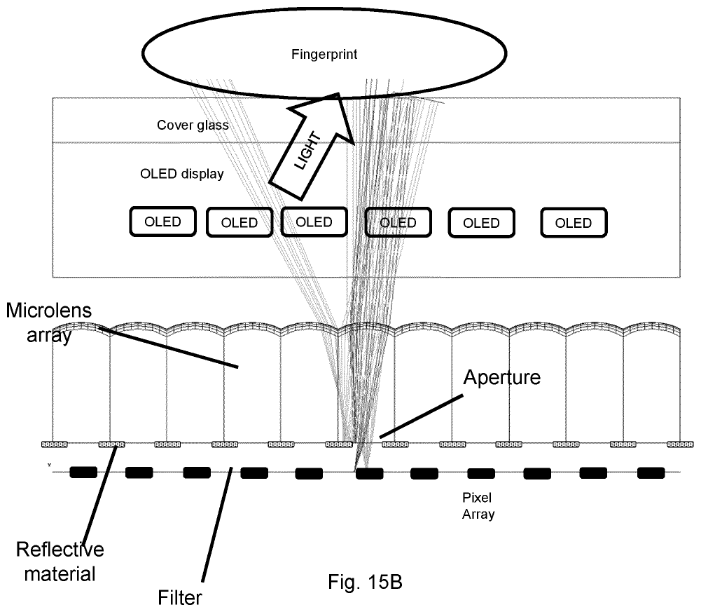

FIG. 14 corresponds to FIG. 12 but the incident angle is now 13°. The result is that the light is focused by the microlens but absorbed by the back side of the microlens structure which is opaque outside of the transparent apertures. I.e. the undesired light with large incident angle is not detected.

FIG. 15A is combination of FIGS. 12-14 showing light reflected from the fingerprint with incident angles of 0, 6 and 13 degrees, respectively. The light source used is the OLED display. The OLED is a convenient light source for the presently disclosed fingerprint sensor. It emits strong enough light and with suitable control it provides uniform illumination. But the OLED provides much background light as well. And furthermore, an OLED display emits visible light. As a result hereof ambient light becomes background light to the pixels as well. This is one of the reasons why an IR light source is preferred.

FIG. 15B illustrates how elements of reflective material can be utilized to replace the absorbent back side surface of the microlens array showed in FIG. 15A. The result is that light can be reflected back towards the fingerprint to increase illumination of the fingerprint, instead of having the photons absorbed in the back side of the microlens structure.

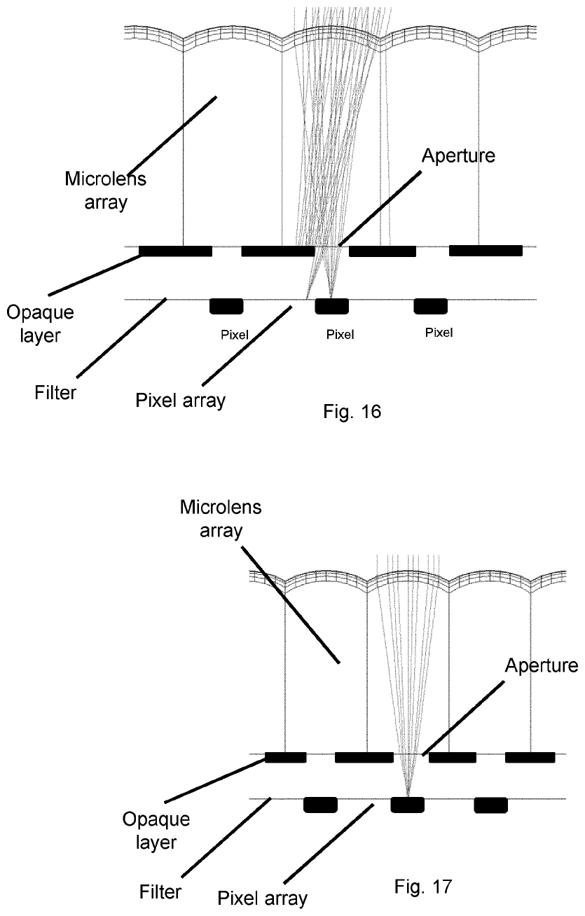

FIG. 16 is a close-up view of FIG. 15A showing the light transmittance through the microlens and aperture. Light with 0 degree incident angle is focused to the pixel, light with 6° incident angle is focused by the microlens and transmitted through the aperture, but does not hit the pixel due to the spacing between back side of microlens and sensor array. Light with 13° incident angle is focused by the microlens but is absorbed by the opaque part of the back side of the microlens.

FIG. 17 is a close-up view of FIG. 12 showing the situation with 0 degrees incident angle.

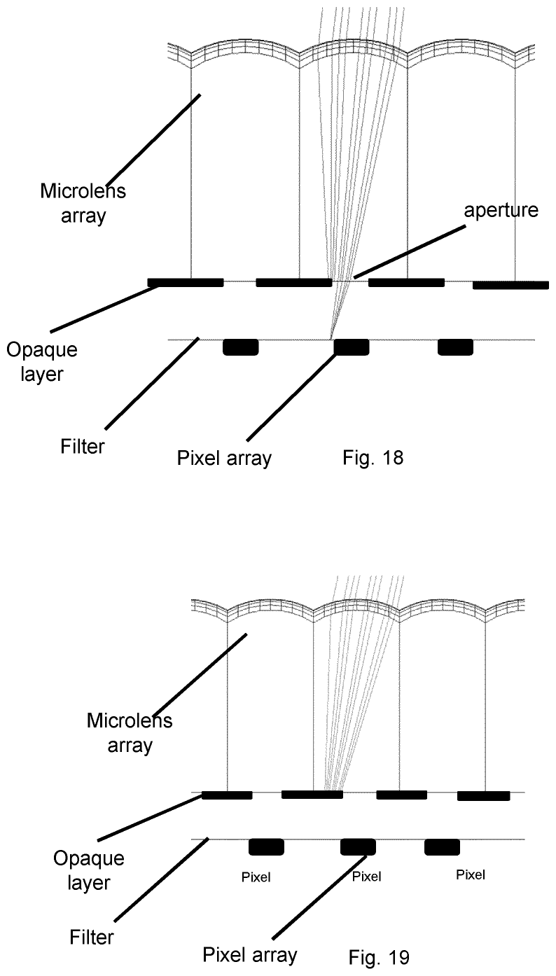

FIG. 18 is a close-up view of FIG. 13 showing the situation with 6 degrees incident angle. Part of the focused light is absorbed by the back side of the microlens, part of the focused light is transmitted through the aperture but does not hit the pixel and is therefore not detected.

FIG. 19 is a close-up view of FIG. 14 showing the situation with 13 degrees incident angle

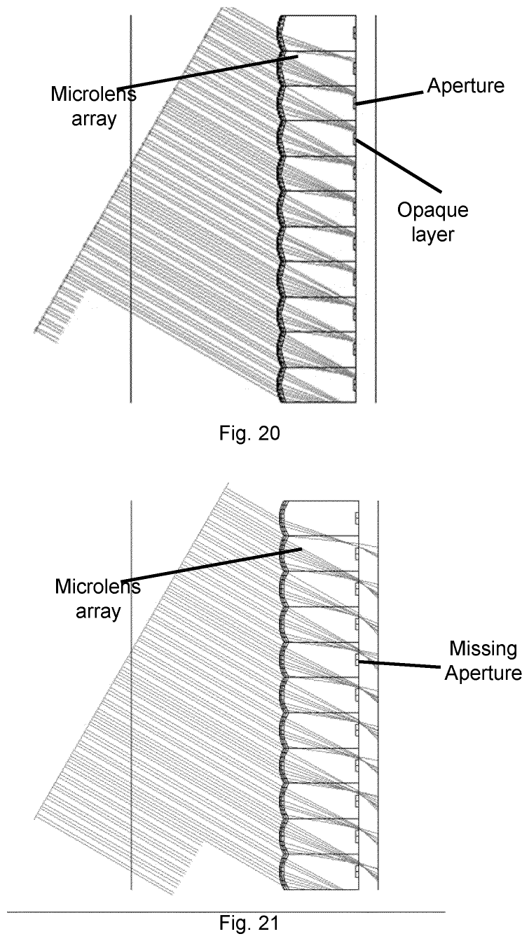

FIG. 20 shows a wavefront of light with 30° incident angle incident on the microlens array shown in FIG. 2. The light is focused by the microlenses but then absorbed by the painted back side surfaces.

FIG. 21 shows a wavefront of light with 30° incident angle incident on the microlens array shown in FIG. 2, however without the apertures, the entire back surface is transparent. And then the light is focused by the microlenses and is transmitted to an adjacent pixel, i.e. undesired light with large incident angle is transmitted to the sensor array. This example illustrates the importance of the transparent aperture in the opaque back side, i.e. they help to ensure that only desired light is transmitted to the sensor array.

FIG. 22 shows a schematic diagram of a microlens array having an elongated aperture. In this case the aperture is substantially elongated along an axis perpendicular to the major plane of the microarray structure. Two wavefronts are shown having incidence angles of 30° and 0°, wherein the wavefront with the higher incident angle does not reach the pixels of the sensor array due to being blocked by the opaque paint on the side of the elongated aperture.

FIG. 23 shows an illustration of the functionality of a microlens array comprising an elongated aperture, wherein the opaque paint makes up the side walls of the elongated aperture. Reflected light from a fingerprint with an incident angle of 6° is blocked by the paint within the elongated aperture. The filter for sorting out undesired wavelengths is shown positioned partly within the elongated aperture.

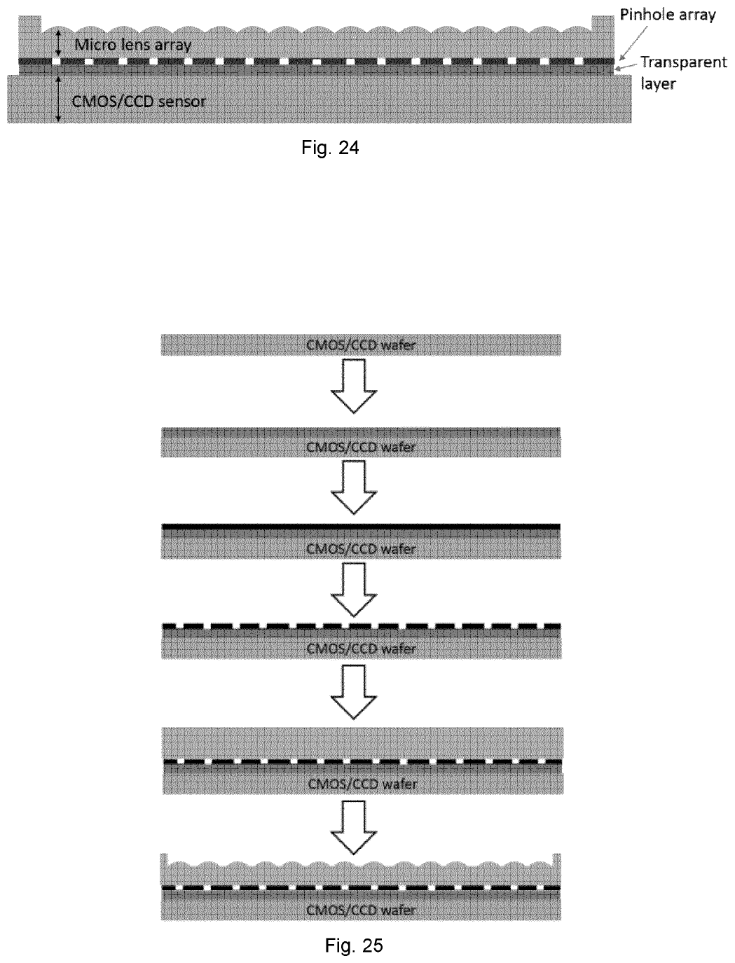

FIG. 24 shows a cut-through side view illustration of one embodiment of the presently disclosed biometric imaging device with a standard CMOS/CCD sensor in the bottom. On the top of the device a microlens array has been provided. Below the microlens array a pinhole/aperture array is provided in an opaque layer. Between the pinhole array and the sensor a (first) transparent substrate layer is provided. Each microlens is precisely aligned with corresponding pinhole in the pinhole array and pixel in the sensor (pixel not shown). The first transparent substrate, the opaque layer with pinholes and the microlens array have all been processed directly on the CMOS/CCD wafer by means of UV-NIL.

FIG. 25 illustrates the process steps of one embodiment of the presently disclosed fabrication method. From the top: A standard CMOS/CCD wafer is provided. On top thereof a first transparent substrate layer is provided, e.g. a transparent polymer. On top thereof a black opaque/non-transparent polymer layer is provided. Pinholes/apertures are subsequently provided in the black polymer layer by means of nanoimprint lithography, e.g. employing hot embossing such that the pinholes of a corresponding mold are stamped into the black polymer layer. The nanoimprint process can ensure that each pinhole is aligned with a corresponding pixel in the sensor array. A second transparent substrate layer is subsequently provided on top of the opaque layer. Subsequent thereto a microlens array is formed in the second transparent substrate by UV-NIL such that each microlens is aligned with a corresponding pinhole array.

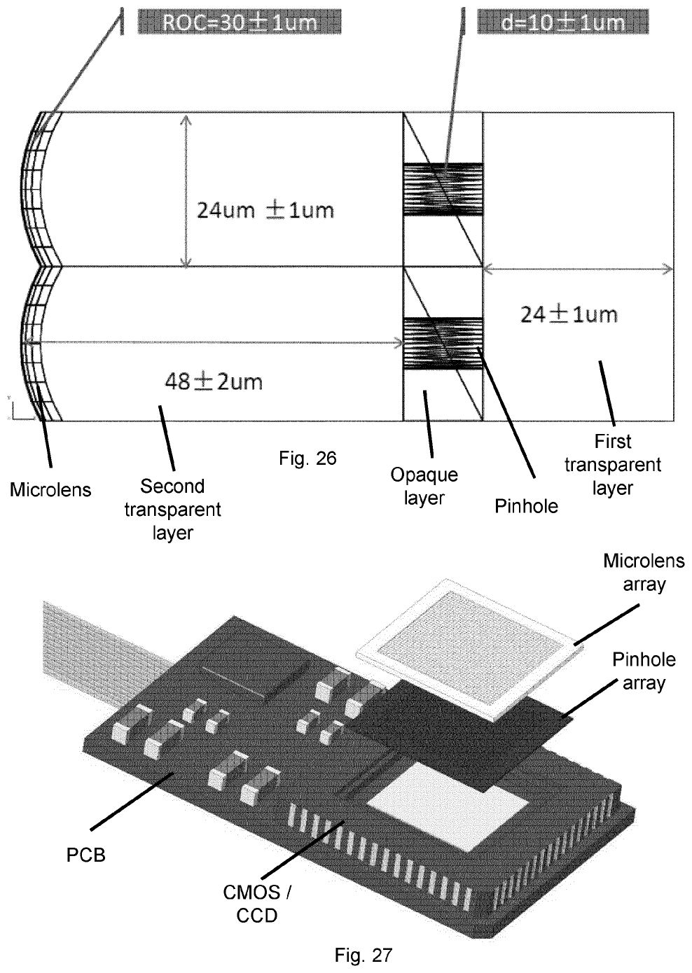

FIG. 26 illustrates a cut-through enlarged view of one embodiment of the structures that are applied on to the photodetector, i.e. microlens including second transparent layer, opaque layer with pinholes and the optional first transparent layer, i.e. the structure that can be provided by means of nanoimprint technology, i.e. the NIL structure. FIG. 26 shows two microlenses with corresponding pinholes and transparent layers. From the left is seen the microlenses which are spherical with a radius of curvature of 30 μm. The microlens structures, which are 24 μm in width, have been formed in the second transparent layer which after microlens formation has a height of 48 μm from the top of the microlens to the top of the opaque layer. The opaque layer has a thickness of 10 μm and the pinholes have a diameter of 10 μm. The first transparent layer between the opaque layer and the pixels (not shown) has a thickness of 24 μm. As seen in FIG. 26 the manufacturing tolerances are as low as ±1 μm, except for the height of the microlens structures, where the tolerance is ±2 μm.

FIG. 27 shows the integration of the biometric imaging device into an electronic device for integration in a e.g. a smartphone for under-display applications. As seen in FIG. 27 the microlens structure is provided on top of the pinhole array which is provided on top of the CMOS/CCD which is integrated on a printed circuit board (PCB), which can be a flex-PCB to make the device thinner. When using the presently disclosed method the microlens array, the pinhole array and the CMOS/CCD wafer will not be separated as illustrated in FIG. 27, because they are fabricated layer by layer on top of each other.

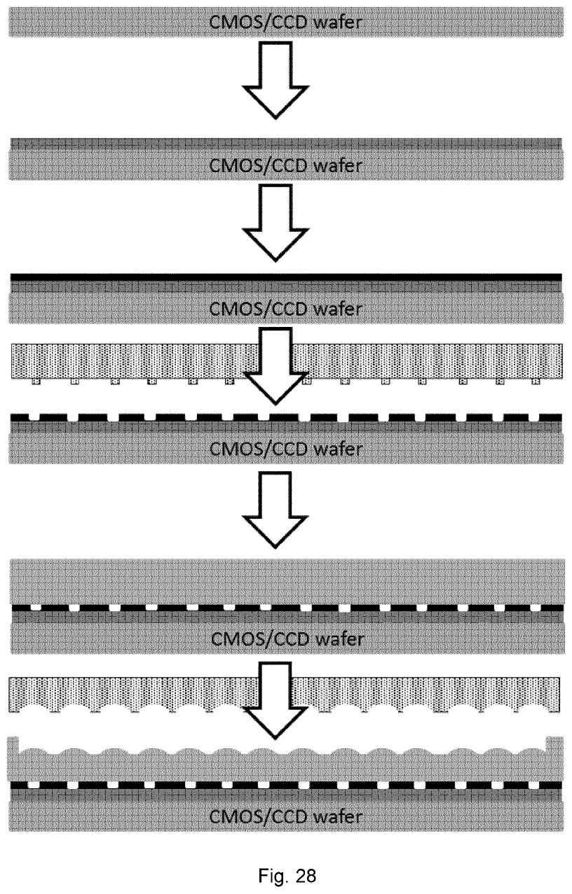

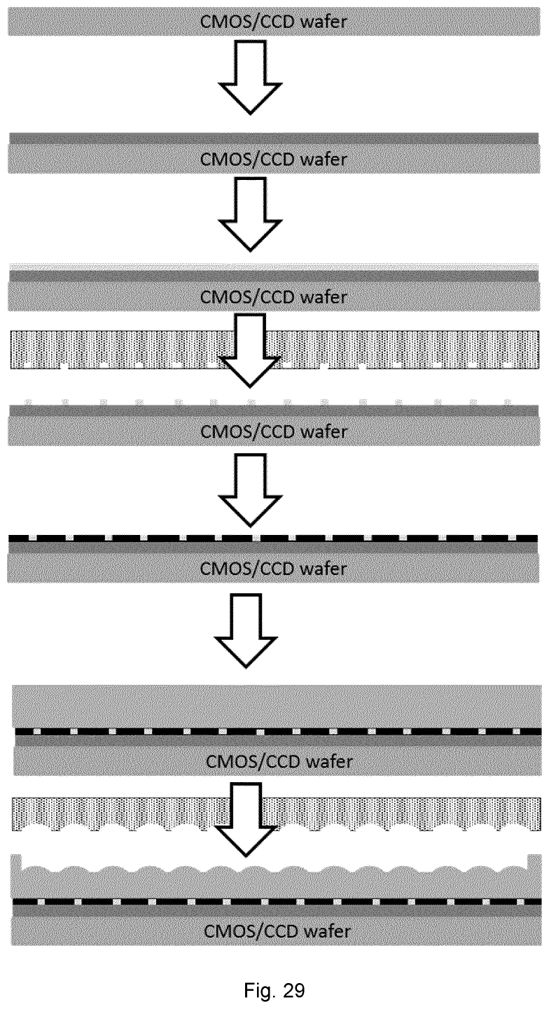

FIG. 28 illustrates the process steps of one embodiment of the presently disclosed fabrication method, where the pinholes are formed by stamping an opaque layer. From the top: A standard CMOS/CCD wafer is provided. On top thereof a first transparent substrate layer is provided, e.g. a transparent polymer. On top thereof a black opaque/non-transparent polymer layer is provided, typically with a thickness of around 1-2 μm. Pinholes/apertures are subsequently provided in the black polymer layer by means of nanoimprint lithography, e.g. employing hot embossing such that the pinholes of a corresponding mold are stamped into the black polymer layer by means of a mold with protruding features for forming the pinhole array, i.e. the protruding features of the mold are stamped through the entire opaque layer to form the transparent pinholes. A second transparent substrate layer is subsequently provided on top of the opaque layer, as seen from the figured the second transparent layer is thicker than the opaque layer. Subsequent thereto a microlens array is formed in the second transparent substrate by UV-NIL by means of a mold with inversed features thereby forming the microlens array.

FIG. 29 illustrates the process steps of one embodiment of the presently disclosed fabrication method, where the pinholes are formed by micro-pillars. From the top: A standard CMOS/CCD wafer is provided. On top thereof a first transparent substrate layer is provided, e.g. a transparent polymer. Micro-pillars are then formed in the first transparent substrate layer by means of a mold with inverse features defining the micro-pillars array. Around the micro-pillar array an opaque/non-transparent (e.g. black) polymer layer is provided, the transparent micro-pillars thereby becoming transparent pinholes in the opaque layer. A second transparent substrate layer is subsequently provided on top of the opaque layer. Subsequent thereto a microlens array is formed in the second transparent substrate by UV-NIL by means of a mold with inversed features thereby forming the microlens array.

1. A method for manufacturing a biometric imaging device, the method comprising the steps of:
providing an image sensor comprising a photodetector pixel array;
forming an opaque layer on the first transparent substrate layer or on the photodetector pixel array, the opaque layer having a transparent pinhole array therein;
arranging a second transparent substrate layer on top of the opaque layer, and
forming a microlens array in the top of the second transparent substrate layer, such that each microlens in the array corresponds to a pinhole in the pinhole array and at least one pixel in the photodetector array,
wherein the opaque layer with the transparent pinhole array and the microlens array is formed by means of nanoimprint lithography.

2. The method according to claim 1, wherein the microlens array is formed such that the focal point of each microlens is in the plane of the photodetector pixel array.

3. The method according to claim 1, wherein a first transparent substrate layer is arranged to cover the image sensor.

4. The method according to claim 3, wherein the first transparent substrate layer is formed by means of nanoimprint lithography.

5. The method according to claim 1, wherein the opaque layer is formed on the first transparent substrate layer or on the photodetector pixel array and subsequently the transparent pinhole array is formed in the opaque layer.

6. The method according to claim 5, wherein the transparent pinhole array is formed in the opaque layer by pressing a first mold, having an array of protruding elements, into the opaque polymer layer to form an array of transparent pinholes in the opaque polymer layer.

7. The method according to claim 1, wherein the transparent pinhole array is formed as an array of transparent micro-pillars on the photodetector pixel array or on the first transparent substrate layer and subsequently the opaque layer is formed around the array of micro-pillars to provide the opaque layer with the array of transparent pinholes.

8. The method according to claim 1, wherein the transparent pinhole array is formed as an array of transparent micro-pillars imprinted in the first transparent substrate layer and subsequently the opaque layer is formed around the array of micro-pillars to provide the opaque layer with the array of transparent pinholes.

9. The method according to claim 1, wherein the microlens array is formed in the second transparent substrate layer by pressing a second mold, having a pattern defining an array of inverse microlenses, into the second transparent layer.

10. The method according to claim 1, wherein the nanoimprint lithography is UV based nanoimprint lithography.

11. The method according to claim 1, wherein the thickness of the first transparent substrate layer is less than 25 μm and/or wherein the thickness of the second transparent substrate layer including the microlens array is less than 50 μm.

12. The method according to claim 1, wherein the thickness of the opaque layer is less than 12 μm and wherein the diameter of each transparent pinhole in the pinhole array is less than 12 μm.

13. The method according to claim 1, wherein the thickness of the opaque layer is less than 5 μm, or less than 2 μm.

14. The method according to claim 1, wherein the radius of curvature of each microlens in the microlens array is between 20 and 40 μm.

15. The method according to claim 1, wherein the layers are arranged and formed such that each pinhole in the pinhole array is aligned with at least one pixel in the pixel array.

16. The method according to claim 1, wherein the pinhole to microlens and/or the pinhole to pixel are aligned within ±1 μm.

17. A biometric imaging device manufactured according to the method of claim 1.

18. The biometric imaging device according to claim 17, wherein the microlens structure is configured to converge an optical signal from above the microlens structure to pinholes in the pinhole array, the optical signal being transmitted to the image sensor array via the pinholes.

19. The biometric imaging device according to claim 17, for placement under a display panel for detecting/imaging light returned from an object on top of the display panel, wherein the device is configured such that object light with an incident angle of less than or equal to a predefined value of 5 degrees is focused by the microlens structure to the sensor array whereas fingerprint light with an incident angle of more than said predefined value of 5 degrees is not detected.

20. The biometric imaging device according to claim 19, wherein the object is a fingerprint located on top of the display panel.

21. The method according to claim 1, wherein the opaque layer with the transparent pinhole array and the microlens array is formed by means of UV based nanoimprint lithography.

22. The method according to claim 3, wherein a first transparent substrate layer is arranged to cover the image sensor before the opaque layer is formed.

23. The method according to claim 4, wherein the first transparent substrate layer is formed by means of UV based nanoimprint lithography.
